(19) United States
(12) Patent Application Publication
(10) Pub. No.: US 2011/0233549 A1
(43) Pub. Date: Sep. 29, 2011

(54) DISPLAY APPARATUS INCLUDING GYRO SENSORS, AND METHOD OF MANUFACTURING THE SAME

(75) Inventor: Sang-Min YI, Yongin-city (KR)

(73) Assignee: SAMSUNG MOBILE DISPLAY CO., LTD., Yongin-city (KR)

(21) Appl. No.: 13/019,245

(22) Filed: Feb. 1, 2011

(30) Foreign Application Priority Data
Mar. 23, 2010 (KR) 10-2010-0025947

(51) Int. Cl. H01L 33/08

(52) U.S. Cl. 257/53; 438/25; 257/E33.056

(57) ABSTRACT

A display apparatus including gyro sensors with a simple structure, and a method of manufacturing the same are disclosed. The display apparatus includes a first substrate and a second substrate, a space between the first substrate and second substrate, including a display area and a non-display area, and a first gyro sensor formed in a sensor area disposed within the non-display area, where the first gyro sensor includes: a first lower base electrode placed at a central portion of the first gyro sensor on the first substrate, a pair of first lower direction electrodes formed to be symmetrical to each other around the first lower base electrode in a first direction on the first substrate, and a first conductor configured to contact with the first lower base electrode within the first gyro sensor.

### CROSS-REFERENCE TO RELATED APPLICATIONS

This application claims priority to and the benefit of Korean Patent Application No. 10-2010-0025947 filed in the Korean Intellectual Property Office on Mar. 23, 2010, the entire contents of which are incorporated herein by reference.

### BACKGROUND

1. Field

The present disclosure relates to a display apparatus having a displacement detection structure built in a non-display area, and a method of manufacturing the same.

2. Description of the Related Technology

A gyro sensor is capable of detecting displacement, angular velocity, and the like by sensing displacement according to the movement of an object and sending an electrical signal according to the sensed displacement. The gyro sensor is widely used in vehicles, shipping equipment, aircraft, and so on.

Recently, the use of the gyro sensor in different industries has been expanding. With the development of mobile communications, demand of gyro sensors has also increased. In line with this demand, the gyro sensor is additionally configured as a module of a chip and added to a display apparatus for a mobile communication terminal, a navigator, and the like.

When the gyro sensor is used in a display apparatus for a mobile communication terminal, the accuracy of the gyro sensor is not imperative. However, an expensive gyro sensor module is typically mounted on recent mobile communication terminals. Accordingly, there are problems in that a process of manufacturing the gyro sensor is complicated and expensive.

The above information disclosed in this Background section is only for enhancement of understanding of the background of the invention.

### SUMMARY OF CERTAIN INVENTIVE ASPECTS

The instant embodiments have been made in an effort to provide a display apparatus including gyro sensors with a simple structure and a method of manufacturing a display apparatus including gyro sensors using an existing manufacturing process.

One aspect is a display apparatus, including: a first substrate and a second substrate, a space between the first substrate and second substrate, including a display area and a non-display area, and a first gyro sensor formed in a sensor area disposed within the non-display area, where the first gyro sensor includes: a first lower base electrode placed at a central portion of the first gyro sensor on the first substrate, a pair of first lower direction electrodes formed to be symmetrical to each other around the first lower base electrode in a first direction on the first substrate, and a first conductor configured to contact with the first lower base electrode within the first gyro sensor.

Another aspect is a display apparatus, including: a first substrate, a second substrate, a display area and a non-display area in a space between the first substrate and the second substrate, a first gyro sensor formed in a sensor area disposed within the non-display area, and conductive sealing members configured to partition the sensor area, where the first gyro sensor includes a first lower base electrode formed on the first substrate and placed at a central portion of the first gyro sensor, and a first conductor configured to contact the first lower base electrode within the first gyro sensor, where at least two of the conductive sealing members are spaced apart from each other with the first lower base electrode interposed therebetween and are arranged in a first direction.

Another aspect is a display apparatus, including: a first substrate, a second substrate, a display area and a non-display area in a space between the first substrate and the second substrate, and a first gyro sensor formed in a sensor area disposed within the non-display area, where the first gyro sensor includes: a first base electrode formed on the first substrate, a pair of first direction electrodes formed at respective edges on both sides of the first gyro sensor in a first direction on the second substrate, and a first conductor configured to contact the first base electrode within the first gyro sensor.

Another aspect is a method of manufacturing a display apparatus, including: forming a thin film transistor circuit on a first substrate, forming a sensor electrode on the first substrate in an outer wall of the thin film transistor circuit, coating a sealing material along a sealing line to partition the sensor area on the first substrate, injecting a conductive liquid into the sensor area, and adhering a second substrate to the first substrate.

### BRIEF DESCRIPTION OF THE DRAWINGS

FIG. 1 is a top plan view schematically showing an embodiment of a display apparatus;

FIG. 2 is a cross-sectional view of a gyro sensor taken along line II-II of FIG. 1;

FIG. 3 is a cross-sectional view of the gyro sensor taken along line III-III of FIG. 2;

FIGS. 4A and 4B are diagrams illustrating operation of an embodiment of the gyro sensor;

FIGS. 5A to 5E are cross-sectional views sequentially illustrating an embodiment of a process of manufacturing an embodiment of a display apparatus;

FIG. 6 is a cross-sectional view of a second embodiment of a gyro sensor;

FIG. 7 is a cross-sectional view of a third embodiment of a gyro sensor;

FIG. 8 is a cross-sectional view of a fourth embodiment of a gyro sensor;

FIG. 9 is a cross-sectional view of a fifth embodiment of a gyro sensor;

FIG. 10 is a cross-sectional view of a sixth embodiment of a gyro sensor; and

FIGS. 11A and 11B are diagrams illustrating the operation of another embodiment of the gyro sensor.

### DETAILED DESCRIPTION OF CERTAIN INVENTIVE EMBODIMENTS

Hereinafter, some exemplary embodiments of the present invention will be described in detail, with reference to the accompanying drawings, in order for those skilled in the art to be able to readily implement them. The size and thickness of each of the elements shown in the drawings is arbitrarily shown for better understanding and ease of description.

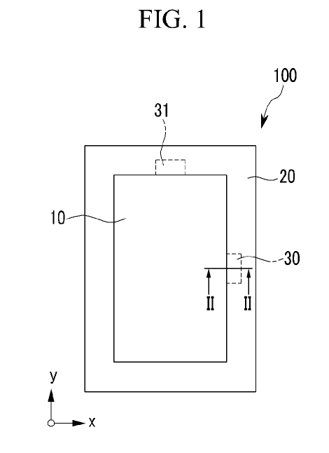

FIG. 1 is a top plan view schematically showing an embodiment of a display apparatus. Referring to FIG. 1, the embodiment of the display apparatus 100 is divided into a display area 10 and a non-display area 20. In some embodiments, the display area 10 refers to a screen display unit on which a screen is displayed, and the non-display area 20 refers to an area necessary for circuit wires other than the display area 10. In one embodiment, where the display apparatus 100 is a liquid crystal display (LCD), an active area may become the screen display unit, and a black matrix may become the non-display area 20.

The embodiment of the display apparatus 100 includes sensor areas 30 and 31 in the non-display area 20. Gyro sensors for detecting displacement, and the like, of the display apparatus 100, are disposed in the respective sensor areas 30 and 31. In the embodiment of FIG. 1, the sensor areas 30 and 31 are illustrated to be formed on the right side and the upper side of the display apparatus 100, respectively. In other embodiments, the sensor areas may be placed in other locations of the non-display area 20.

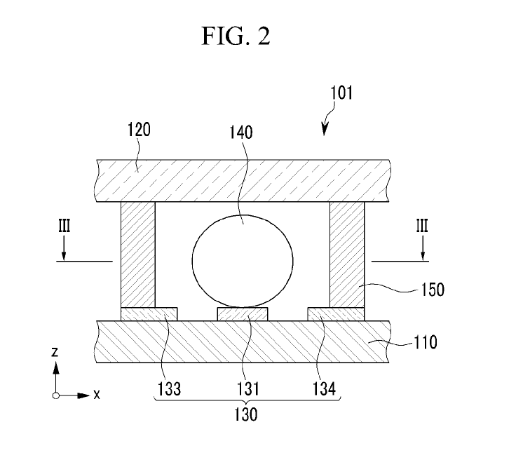

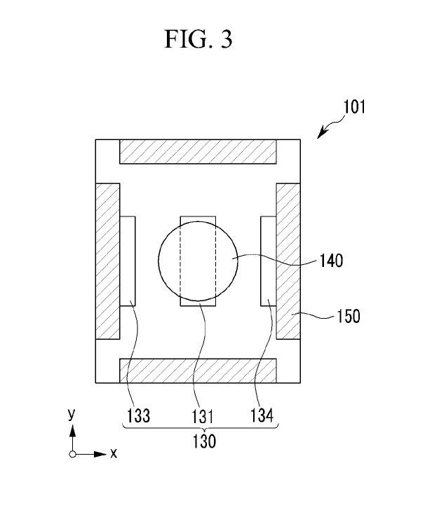

FIG. 2 is a cross-sectional view of a gyro sensor taken along line II-II of FIG. 1, and FIG. 3 is a cross-sectional view of the gyro sensor taken along line III-III of FIG. 2. An embodiment of the gyro sensor built in the display apparatus is described below with reference to FIGS. 2 and 3.

An embodiment of the gyro sensor 101 includes a sensor electrode 130 and a conductor 140. The sensor electrode 130 includes a base electrode 131 and a pair of first direction electrodes 133 and 134. Referring to FIGS. 1 through 3, the base electrode 131 is placed at the central portion of the sensor area 30. The first direction electrodes 133 and 134 are symmetrically disposed with the base electrode 131 interposed therebetween in an x-axis direction (also referred to as a first direction).

The gyro sensor 101 is placed in the sensor area 30 of the non-display area 20. The sensor area 30 is partitioned by sealing members 150 between a first substrate 110 and a second substrate 120. The sealing members 150 function to adhere the first substrate 110 and the second substrate 120 together. The sealing members 150 are formed to surround the circumference of the conductor 140 so that the conductor 140 is placed within the sensor area 30. Accordingly, the sealing members 150 function to protect the conductor 140 and also to separate the sensor area 30 from the non-display area 20, and from the display area 10 in which the gyro sensor 101 is not disposed.

In the embodiment shown in FIG. 3, the sealing members 150 are spaced apart from each other without being connected together and are formed to surround the four sides of the circumference of the conductor 140. In other embodiments, the sealing members 150 may be modified such that the conductor 140 does not come out from the sensor area 30. In one embodiment, the sealing member 150 may be integrally formed around the conductor 140. Further, in the embodiment shown in FIG. 2, the sealing members 150 are formed on the first direction electrodes 133 and 134. In other embodiments, the sealing members 150 may be formed to adjoin the first direction electrodes 133 and 134 so that they are disposed within the sensor area 30.

In the sensor area 30, the conductor 140 is in contact with the base electrode 131 and may also be in contact with either of the first direction electrodes 133 and 134. When the conductor 140 is in contact with the base electrode 131 and with either of the first direction electrodes 133 and 134, current flows therethrough by the conductor 140, enabling displacement, and the like to be detected. In some embodiments, the conductor 140 may made of a conductive liquid, such as, for example, a conductive ink with high viscosity. In other embodiments, the conductor 140 may be made of a conductive solid, including various metals.

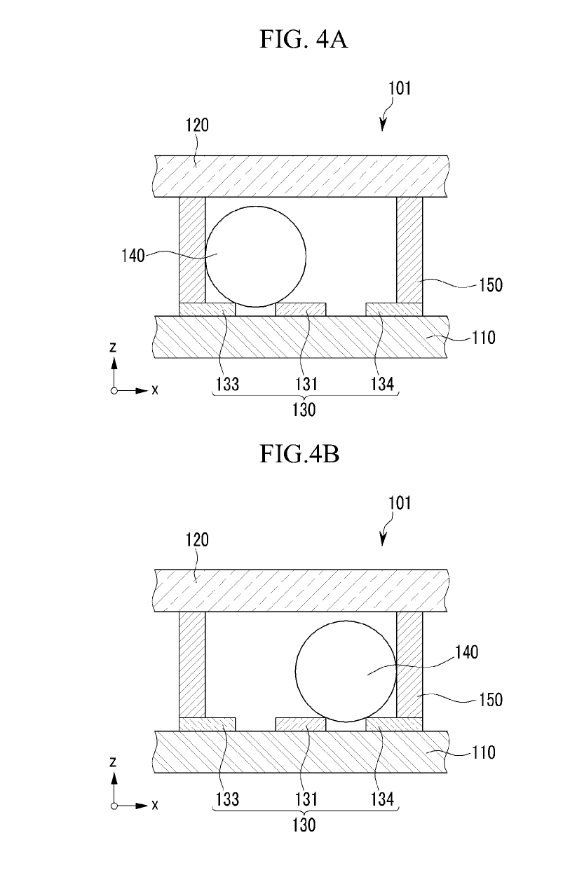

FIGS. 4A and 4B are diagrams illustrating operation of an embodiment of the gyro sensor. Referring to FIG. 4A, if the display apparatus 100 moves toward the first direction electrode 134 in a positive (+) x-axis direction, the conductor 140 within the sensor area 30 moves toward the first direction electrode 133 in the opposite direction by inertia. Current flows through the base electrode 131 and the first direction electrode 133 through the medium of the conductor 140. Accordingly, it can be determined that the display apparatus 100 has moved in the positive (+) x-axis direction or acceleration has occurred in the positive (+) x-axis direction based on the flow of current.

Referring to FIG. 4B, if the display apparatus 100 moves toward the first direction electrode 133 in a negative (−) x-axis direction, the conductor 140 within the sensor area 30 moves toward the first direction electrode 134 in the opposite direction by inertia. Current flows through the base electrode 131 and the first direction electrode 134 through the medium of the conductor 140. Accordingly, it can be determined that the display apparatus 100 has moved in the negative (−) x-axis direction or acceleration has occurred in the negative (−) x-axis direction based on the flow of current.

In other words, the displacement, and the like, of the display apparatus 100 in the x-axis direction can be detected through the gyro sensor 101, which includes the conductor 140 and the sensor electrode 130.

The direction electrodes of the gyro sensor 101 disposed in the sensor area 30 on the upper side of the display apparatus 100 are disposed in a y-axis direction (also referred to as a second direction) on the basis of a base electrode so that the gyro sensor 101 can detect the displacement, and the like of the display apparatus 100 in the y-axis direction. The remaining construction of the gyro sensor is the same as that of the gyro sensor 101 disposed in the sensor area 30 on the right side of the display apparatus 100.

As described above, one embodiment of the display apparatus 100 includes the sensor area 30, which in turn includes the respective gyro sensors, within the non-display area 20 on the upper and right sides of the display apparatus 100. Accordingly, the displacement of the display apparatus 100 in the two axes can be detected.

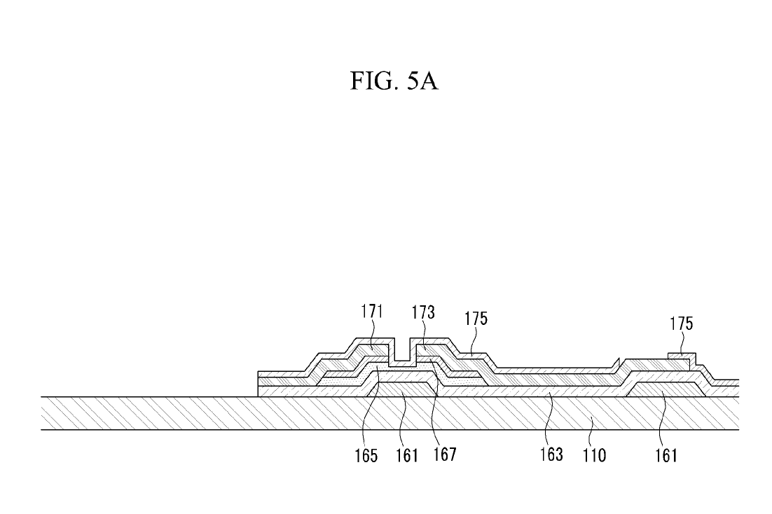

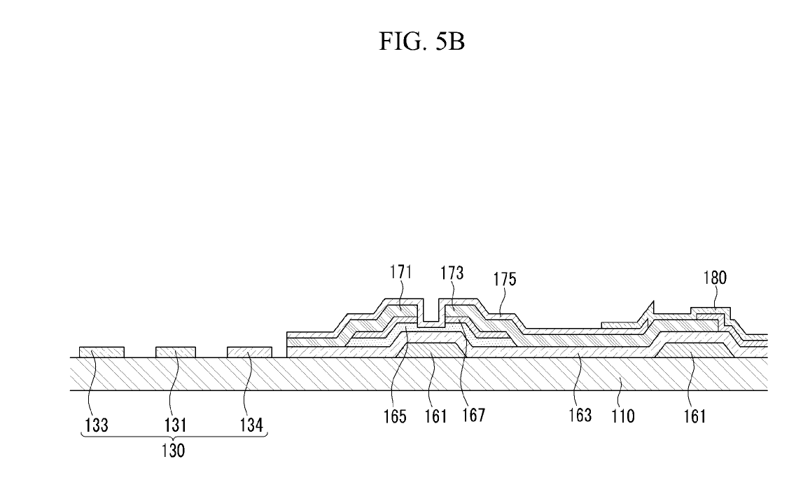

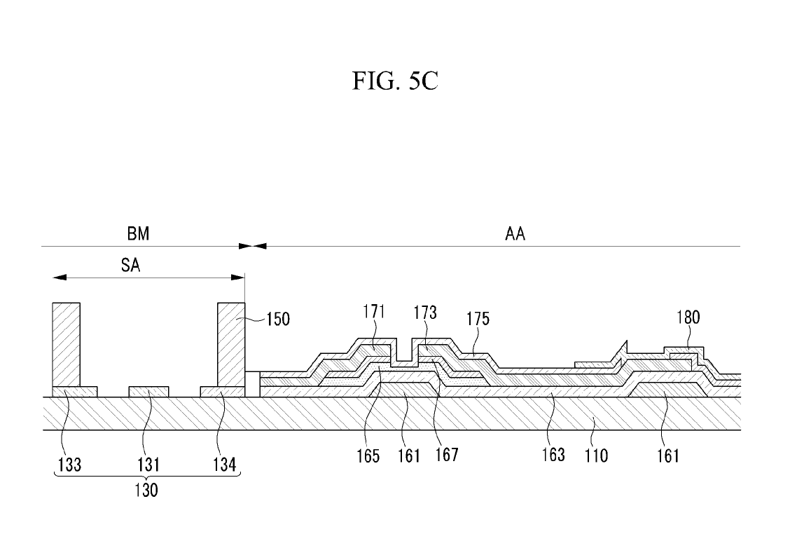

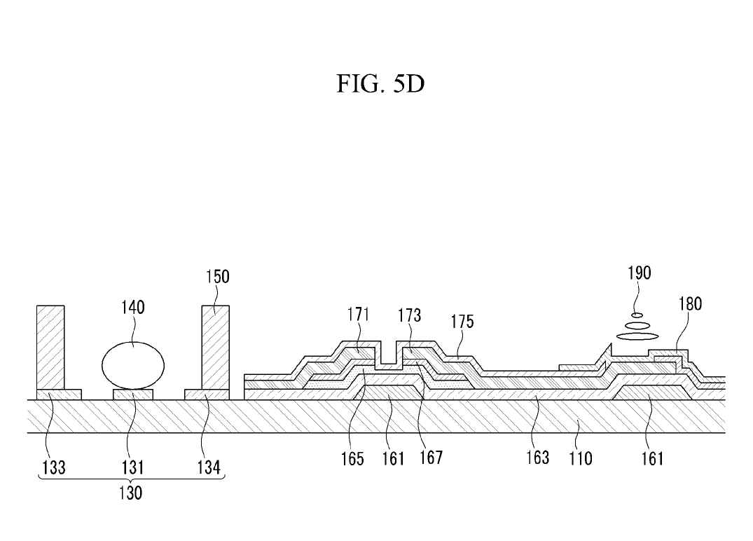

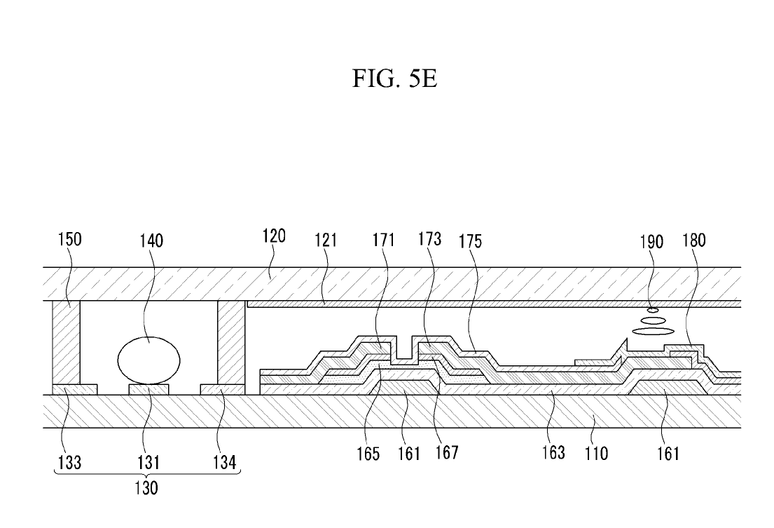

FIGS. 5A to 5E are cross-sectional views sequentially illustrating an embodiment of a process of manufacturing an embodiment of the display apparatus (assuming that the display apparatus is an LCD). The embodiment of a method of manufacturing the display apparatus including the gyro sensors is described in detail below with reference to FIGS. 5A to 5E.

Referring to FIG. 5A, gate lines (not shown) including respective gate electrodes 161 are formed on a first substrate 110. The first substrate 110 may be formed of an insulation material, and the gate lines and the gate electrodes 161 may be made of various metals and conductors.

A gate insulating layer 163, made of silicon nitride (SiNx), silicon oxide (SiOx), or the like, is formed on the gate electrodes 161, and a semiconductor layer 165 made of polysilicon is formed on the gate insulating layer 163. A resistive contact layer 167, such as an amorphous silicon or silicide layer doped with phosphorous (P) or an n-type or p-type impurity at a high concentration, is formed on the semiconductor layer 165. A source electrode 171 and a drain electrode 173, made of a conducting material with low resistance, are formed on the resistive contact layer 167 and the gate insulating layer 163. Further, a protective layer 175 is formed on the source electrode 171, the drain electrode 173, and an exposed portion of the semiconductor layer 165. The protective layer 175 can be made of an organic insulating material or the like.

FIG. 5B is a diagram showing a step of forming a pixel electrode and a sensor electrode. The pixel electrode 180 is formed to be physically and electrically connected to the drain electrode 173 on the protective layer 175. The pixel electrode 180 can be formed of a transparent electrode, such as indium tin oxide (ITO) or indium zinc oxide (IZO). In one embodiment, the sensor electrode 130 for forming the gyro sensor is formed in the non-display area simultaneously with the pixel electrode 180. The sensor electrode 130 includes the base electrode 131 and the pair of first direction electrodes 133 and 134. The sensor electrode 130 does not necessarily need to be formed of a transparent electrode, such as ITO or IZO, because it is formed in the non-display area. However, to simplify the process, in some embodiments, the sensor electrode 130 can be formed as a transparent electrode like the pixel electrode 180.

FIG. 5C is a diagram showing a step of forming the sealing members. The first substrate 110 and the second substrate 120 (not shown on FIG. 5C) of the display apparatus 100 are adhered together. To partition the sensor area, the sealing members 150 are formed using a sealant dispenser. The sealing members 150 function to partition the display area AA, the non-display area BM, and the sensor area SA. The sealing members 150 also function to protect liquid crystals 190 (shown in FIG. 5D) within the display area 10 and the conductor 140 (shown in FIG. 5D) within the sensor area 30.

FIG. 5D is a diagram showing a step of forming the liquid crystals 190 and the conductor 140. Appropriate portions of the display area 10 are filled with the liquid crystals 190 using liquid crystal drop equipment and, the conductor 140 of the gyro sensor is formed within the sensor area 30 partitioned by the sealing members 150. In one embodiment, since the conductor 140 is made of a conductive liquid, the process of forming the conductor 140 and the process of forming the liquid crystals 190 may be performed at the same time. Accordingly, the process may be simplified.

Referring to FIG. 5E, the second substrate 120 is adhered to the first substrate 110 by the sealing members 150. A common electrode 121 is formed in a portion corresponding to the display area on the second substrate 120. In some embodiments, color filter, and other layers may be further formed on the second substrate 120.

In accordance with one embodiment of the method of manufacturing the display apparatus including the gyro sensors, the gyro sensors with a simple structure can be manufactured using a straightforward manufacture process. Accordingly, the process can be simplified, and the efficiency of the process can be improved.

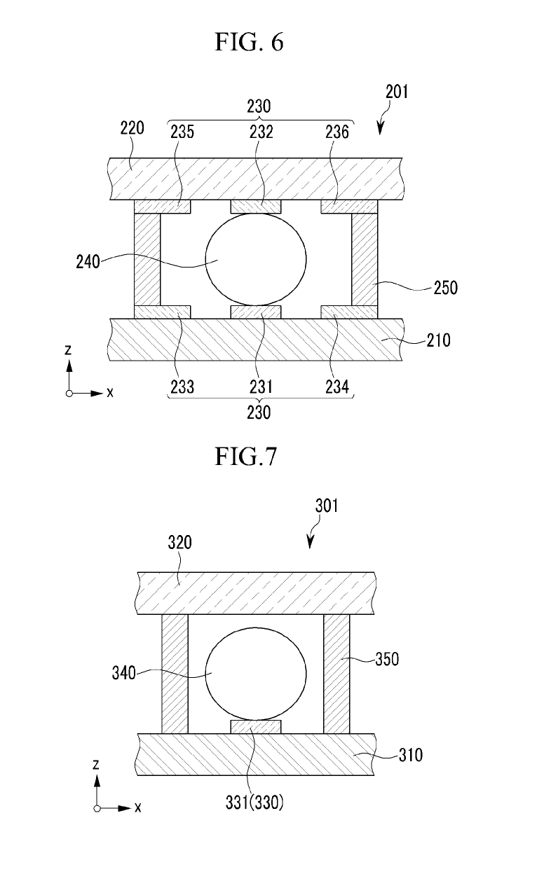

Hereinafter, a display apparatus including gyro sensors according to some exemplary embodiments of the present inventions is described with reference to FIGS. 6 to 11B. In the exemplary embodiments, the construction of elements already described in relation to the embodiment of FIG. 1 will not be repeated.

FIG. 6 is a cross-sectional view of another embodiment of a gyro sensor 201. The gyro sensor 201 includes a sensor electrode 230 and a conductor 240. The sensor electrode 230 includes a lower base electrode 231 and a pair of first lower direction electrodes 233 and 234 formed on a first substrate 210, and an upper base electrode 232 and a pair of first upper direction electrodes 235 and 236 formed on a second substrate 220. Further, sealing members 250 are formed to surround the circumference of the conductor 240 so that the conductor 240 is disposed within a sensor area. Accordingly, the sealing members 250 function to protect the conductor 240 and also to separate the sensor area in which the gyro sensor 201 is placed from a non-display area, and a display area in which the gyro sensor 201 is not placed. In some embodiments, the conductor 240 may be made of a conductive liquid having a high viscosity or a conductive solid.

In the embodiment of FIG. 6, the base electrode and the direction electrodes are formed on the second substrate 220 (an upper substrate) in addition to the first substrate. Accordingly, the displacement of the conductor 240 according to the movement of a display apparatus can be detected more easily. Further, the upper base electrode 232 and the first upper direction electrodes 235 and 236 may be formed at the same time with a process of forming a common electrode on the second substrate 220. Accordingly, the process can be simplified as described above.

FIG. 7 is a cross-sectional view of another embodiment of a gyro sensor 301. The gyro sensor 301 includes a conductor 340 and a sensor electrode 330 including a base electrode 331. The base electrode 331 is formed on a first substrate 310 opposite to a second substrate 320. Further, sealing members 350 are formed to surround the circumference of the conductor 340 so that the conductor 340 is placed within a sensor area. Accordingly, the sealing members 350 function to protect the conductor 340 and also to separate the sensor area in which the gyro sensor 301 is placed from a non-display area, and a display area in which the gyro sensor 301 is not placed. In some embodiments, the conductor 340 may be made of a conductive liquid having a high viscosity, or a conductive solid.

In the embodiment of FIG. 7, the sealing members 350 placed on both sides in an x-axis direction, and are made of a conductive material. The base electrode 331 is interposed between the sealing members 350, and is made of a conductive material without forming the direction electrodes on each of the substrates 310 and 320. Accordingly, the sealing members 350 may function as the direction electrodes. Referring to FIG. 7, if the display apparatus moves, the conductor 340 moves in the x-axis direction by inertia and so the conductor 340 can be simultaneously brought into contact with the base electrode 331 and the sealing members 350. Current flows through the sealing members 350 through the medium of the conductor 340. Accordingly, the displacement, and the like, of the display apparatus can be detected by sensing an electrical signal. The sealing members 350 in the embodiment of FIG. 7, are not integrally formed on the circumference of the conductor 340, but are spaced apart from each other along four faces on the circumference of the conductor 340.

In one embodiment, the sealing members 350 are made of a conductive material and used as the direction electrodes. Accordingly, the displacement of the conductor 340 according to the movement of the display apparatus can be easily detected.

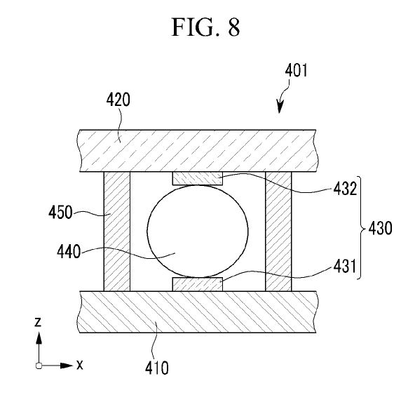

FIG. 8 is a cross-sectional view of another embodiment of a gyro sensor 401. The gyro sensor 401 includes a sensor electrode 430 and a conductor 440. The sensor electrode 430 includes a lower base electrode 431 formed on a first substrate 410, and an upper base electrode 432 formed on a second substrate 420. Further, sealing members 450 are formed to surround the circumference of the conductor 440 so that the conductor 440 is placed within a sensor area. Accordingly, the sealing members 450 function to protect the conductor 440 and also to separate the sensor area in which the gyro sensor 401 is placed from a non-display area, and a display area in which the gyro sensor 401 is not placed. In one embodiment, the conductor 440 may be made of a conductive liquid having a high viscosity, or a conductive solid.

In the embodiment of FIG. 8, the sealing members 450 are placed on both sides in an x-axis direction with the base electrode 331 interposed therebetween, and the base electrode is made of a conductive material. Direction electrodes are not formed on each of the substrates. The sealing members 450 may function as the direction electrodes. Referring to FIG. 8, if the display apparatus moves, the conductor 440 moves in the x-axis direction by inertia and so the conductor 440 can be simultaneously brought into contact with the lower base electrode 431, the upper base electrode 432, and the sealing members 450. Current flows through the sealing members 450 through the medium of the conductor 440. Accordingly, the displacement, and the like, of the display apparatus may be detected by sensing an electrical signal. Accordingly, the sealing members 450 in the embodiment of FIG. 8 are not integrally formed on the circumference of the conductor 440, but are spaced apart from each other along four faces on the circumference of the conductor 440.

In the embodiment shown in FIG. 8, the sealing members 450 made of a conductive material are used as the direction electrodes. Accordingly, the displacement of the conductor 440 according to the movement of the display apparatus can be easily detected. Further, since the upper base electrode 432 is added on the second substrate 420, the displacement of the conductor 440 according to the movement of the display apparatus can be more easily detected.

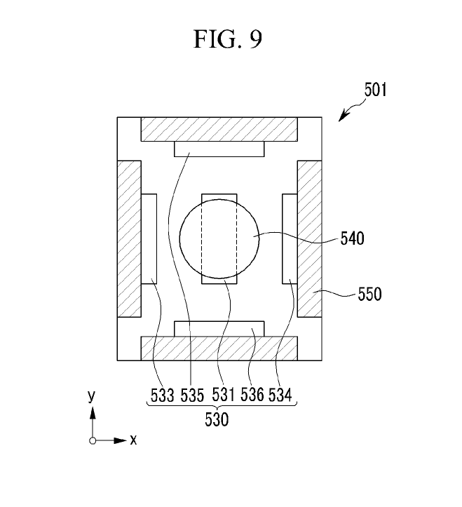

FIG. 9 is a cross-sectional view of another embodiment of a gyro sensor 501. This figure is a cross-sectional view of an embodiment of the gyro sensor 501 taken on a plane surface. The gyro sensor 501 includes a sensor electrode 530 and a conductor 540. The sensor electrode 530 includes a base electrode 531, a pair of first direction electrodes 533 and 534, and a pair of second direction electrodes 535 and 536 that are disposed on a first substrate (also referred to as a lower substrate). Sealing members 550 are formed to surround the circumference of the conductor 540 so that the conductor 540 is placed within a sensor area. Accordingly, the sealing members 550 function to protect the conductor 540 and also to separate the sensor area in which the gyro sensor 501 is placed from a non-display area, and a display area in which the gyro sensor 501 is not placed. In one embodiment, the conductor 540 may be made of a conductive liquid having a high viscosity, or a conductive solid.

In one embodiment, the gyro sensor 501 further includes the second direction electrodes 535 and 536 symmetrically disposed in a y-axis direction, in addition to the first direction electrodes 533 and 534 symmetrically disposed in an x-axis direction with the base electrode 531 disposed at the central portion of the gyro sensor 501, on the first substrate.

Accordingly, in the previous embodiments, one gyro sensor 501 can detect only displacement in one direction (for example in an x-axis direction), while in the embodiment of FIG. 9, the gyro sensor 501 can detect displacement in two directions (for example, in an x-axis direction and in a y-axis direction). Furthermore, the display apparatus including the gyro sensors can be manufactured using a straightforward manufacture process. Accordingly, the process can be simplified, and the efficiency of the process can be improved.

The embodiment of FIG. 9 may be modified in various ways, similar to the previously described embodiments.

In one embodiment, an upper base electrode, first upper direction electrodes, and second upper direction electrodes disposed on the second substrate may be further included in the gyro sensor 501. The upper base electrode, the first upper direction electrodes, and the second upper direction electrodes are disposed to face a lower base electrode, first lower direction electrodes, and second lower direction electrodes, respectively, disposed on a first substrate. Accordingly, the displacement of the conductor according to the movement of a display apparatus can be more easily detected. Further, the upper base electrode and the first and second upper direction electrodes can be formed simultaneously with a process of forming a common electrode on a second substrate. Accordingly, a display apparatus including the gyro sensors can be manufactured through a straightforward process.

In another embodiment, a base electrode is formed on a first substrate, but sealing members are made of a conductive material without additionally forming a pair of first direction electrodes and a pair of second direction electrodes. Accordingly, the sealing members can function as the direction electrodes. The sealing members on four faces, partitioning a sensor area with the base electrode placed at the center, are made of a conductive material. Accordingly, the displacement of the conductor according to the movement of a display apparatus can be more easily detected. However, in if the sealing members formed on the respective four faces were adjacent to each other, a direction would not be accurately detected. For this reason, the sealing members formed on the respective four faces are formed to not adjoin each other in some embodiments.

In a third embodiment, a pair of first direction electrodes and a pair of second direction electrodes are not separately formed, but sealing members are made of a conductive material. Accordingly, the sealing members can function as the direction electrodes. Further, the sealing members on four faces partitioning a sensor area with a base electrode placed at the center are made of a conductive material. Further, since an upper base electrode is added on a second substrate, the displacement of a conductor according to the movement of a display apparatus can be more easily detected. However, if the sealing members formed on the respective four faces were adjacent to each other, a direction would not be accurately detected. For this reason, in some embodiments, the sealing members formed on the respective four faces are formed to not adjoin each other.

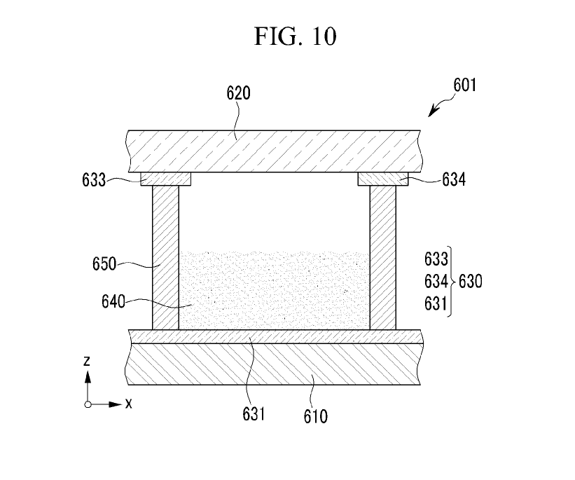

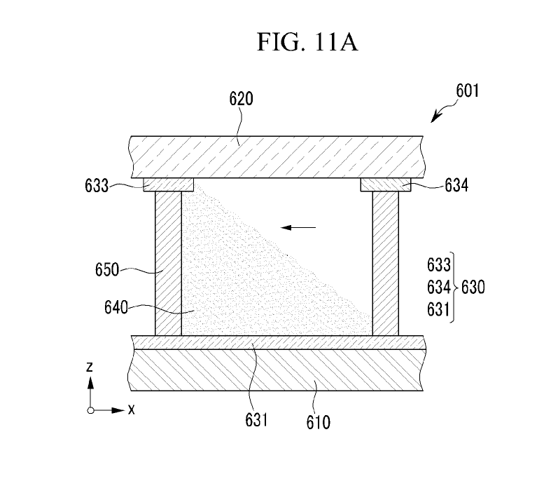

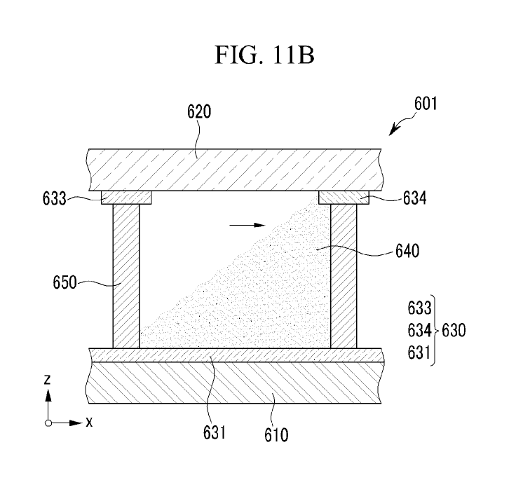

FIG. 10 is a cross-sectional view of another embodiment of a gyro sensor 601. FIGS. 11A and 11B are diagrams illustrating the operation of an embodiment of the gyro sensor 601.

Referring to FIG. 10, the gyro sensor 601 includes a sensor electrode 630 and a conductor 640. The sensor electrode 630 includes a base electrode 631 disposed on a first substrate 610 and a pair of first direction electrodes 633 and 634 disposed on a second substrate 620. In the embodiment of FIG. 10, the base electrode 631 is formed on the entire length on the first substrate 610 in an x-axis direction. The first direction electrodes 633 and 634 are formed at both edges of a sensor area on the second substrate 620 in the x-axis direction. Further, sealing members 650 are formed to surround the circumference of the conductor 640 so that the conductor 640 is placed within a sensor area. Accordingly, the sealing members 650 function to protect the conductor 640 and also to separate the sensor area in which the gyro sensor 601 is placed from a non-display area and a display area in which the gyro sensor 601 is not placed.

In the embodiment of FIG. 10, the conductor 640 is made of a conductive liquid with a low viscosity, such as water including ions. The operation of the embodiment of the gyro sensor 601 is described below with reference to FIGS. 11A and 11B.

Referring to FIG. 11A, if a display apparatus moves toward the first direction electrode 634 in a positive (+) x-axis direction, the conductor 640 made of conductive liquid with a low viscosity moves toward the first direction electrode 633 in the opposite direction by inertia. Current flows through the base electrode 631 and the first direction electrode 633 through the medium of the conductor 640. Accordingly, it can be determined that the display apparatus has moved in the positive (+) x-axis direction or acceleration has occurred in that direction based on the flow of current.

Referring to FIG. 11B, if the display apparatus moves toward the first direction electrode 633 in a negative (−) x-axis direction, the conductor 640 made of conductive liquid with a low viscosity moves toward the first direction electrode 634 in the opposite direction by inertia. Current flows through the base electrode 631 and the first direction electrode 634 through the medium of the conductor 640. Accordingly, it can be determined that the display apparatus has moved in the negative (−) x-axis direction or acceleration has occurred in that direction based on the flow of current.

In the embodiment of FIG. 10, a conductive liquid with a low viscosity is used as the conductor 640, and the sensor electrode 630 constructed as above can detect the displacement, and the like of the display apparatus in the x-axis direction, through the same operation as described with reference to FIGS. 4A and 4B.

In some embodiments, an additional gyro sensor capable of detecting the y-axis direction may be included. In some embodiments, second direction electrodes may be included in one gyro sensor. The embodiment of FIG. 10 may include a variety of variations.

Although the present disclosure has been described in connection with certain exemplary embodiments and exemplary variations thereof, the present disclosure is not limited to the exemplary embodiments and the exemplary variations. For example, in other embodiments, multiple pairs of direction electrodes may be formed. In some other embodiments, the gyro sensor may be used in other display apparatuses, such as organic light emitting diode (OLED) displays.

While this disclosure has been described in connection with certain exemplary embodiments, it is to be understood that the disclosure is not limited to the disclosed embodiments, but, on the contrary, is intended to cover various modifications and equivalent arrangements included within the spirit and scope of the appended claims.

What is claimed is:

1. A display apparatus, comprising:
a first substrate and a second substrate;
a space between the first substrate and second substrate, comprising a display area and a non-display area; and
a first gyro sensor formed in a sensor area disposed within the non-display area,
wherein the first gyro sensor comprises:
a first lower base electrode placed at a central portion of the first gyro sensor on the first substrate;
a pair of first lower direction electrodes formed to be symmetrical to each other around the first lower base electrode in a first direction on the first substrate; and
a first conductor configured to contact with the first lower base electrode within the first gyro sensor.

2. The display apparatus of claim 1, wherein the first gyro sensor further comprises:
a first upper base electrode formed on the second substrate and configured to face the first lower base electrode; and
a pair of first upper direction electrodes formed to be symmetrical to each other around the first upper base electrode in the first direction on the second substrate.

3. The display apparatus of claim 1, wherein the first gyro sensor further comprises a pair of second lower direction electrodes formed to be symmetrical to each other around the first lower base electrode in a second direction crossing the first direction on the first substrate.

4. The display apparatus of claim 1, wherein the first conductor comprises one of a conductive liquid and a conductive solid.

5. The display apparatus of claim 1, further comprising sealing members for adhering the first substrate and the second substrate together and partitioning the display area, the non-display area, and the sensor area.

6. The display apparatus of claim 5, wherein the first lower direction electrodes are configured to adjoin the sealing members.

7. The display apparatus of claim 1, further comprising a second gyro sensor formed in the sensor area separately from the first gyro sensor, wherein the second gyro sensor comprises:
a second lower base electrode disposed at a central portion of the second gyro sensor on the first substrate;
a pair of second lower direction electrodes formed to be symmetrical to each other around the second lower base electrode in a second direction crossing the first direction on the first substrate; and
a second conductor configured to contact the second lower base electrode within the second gyro sensor.

8. The display apparatus of claim 7, wherein the first gyro sensor and the second gyro sensor are disposed at edges on a same side of the non-display area.

9. The display apparatus of claim 7, wherein the first gyro sensor and the second gyro sensor are disposed at edges on different sides of the non-display area.

10. A display apparatus, comprising:
a first substrate;
a second substrate;
a display area and a non-display area in a space between the first substrate and the second substrate;
a first gyro sensor formed in a sensor area disposed within the non-display area; and
conductive sealing members configured to partition the sensor area,
wherein the first gyro sensor comprises
a first lower base electrode formed on the first substrate and placed at a central portion of the first gyro sensor, and
a first conductor configured to contact the first lower base electrode within the first gyro sensor,
wherein at least two of the conductive sealing members are spaced apart from each other with the first lower base electrode interposed therebetween and are arranged in a first direction.

11. The display apparatus of claim 10, wherein the first gyro sensor further comprises a first upper base electrode formed to face the first lower base electrode on the second substrate.

12. The display apparatus of claim 10, wherein at least two of the conductive sealing members are spaced apart from each other with the first lower base electrode interposed therebetween, and are arranged in a second direction crossing the first direction.

13. The display apparatus of claim 10, wherein the first conductor comprises one of a conductive liquid and a conductive solid.

14. The display apparatus of claim 10, further comprising a second gyro sensor formed in the sensor area separately from the first gyro sensor, wherein the second gyro sensor comprises:
a second lower base electrode disposed at a central portion of the second gyro sensor on the first substrate; and
a second conductor configured to contact the second lower base electrode within the second gyro sensor.

15. A display apparatus, comprising:
a first substrate;
a second substrate;
a display area and a non-display area in a space between the first substrate and the second substrate; and
a first gyro sensor formed in a sensor area disposed within the non-display area,
wherein the first gyro sensor comprises:
a first base electrode formed on the first substrate;
a pair of first direction electrodes formed at respective edges on both sides of the first gyro sensor in a first direction on the second substrate; and
a first conductor configured to contact the first base electrode within the first gyro sensor.

16. The display apparatus of claim 15, wherein the first base electrode is lengthily formed to connect the edges on both sides in the first direction.

17. The display apparatus of claim 15, wherein the first conductor comprises a conductive liquid.

18. The display apparatus of claim 15, further comprising a second gyro sensor formed in the sensor area separately from the first gyro sensor,
wherein the second gyro sensor comprises:
a second base electrode formed on the first substrate;
a pair of second direction electrodes formed at respective edges on both sides of the second gyro sensor in a second direction crossing the first direction on the second substrate; and
a second conductor configured to contact the second base electrode within the second gyro sensor.

19. A method of manufacturing a display apparatus, comprising:
forming a thin film transistor circuit on a first substrate;
forming a sensor electrode on the first substrate in an outer wall of the thin film transistor circuit;
coating a sealing material along a sealing line to partition the sensor area on the first substrate;
injecting a conductive liquid into the sensor area; and
adhering a second substrate to the first substrate.

20. The method of claim 19, further comprising additionally forming, on the second substrate, a second sensor electrode opposite to the sensor electrode on the first substrate.

21. The method of claim 19, wherein forming the thin film transistor circuit includes forming a drain electrode and a protective layer, and
forming the sensor electrode includes forming a pixel electrode on the drain electrode and the protective layer and forming the sensor electrode.

22. The method of claim 21, wherein the pixel electrode and the sensor electrode comprise one of indium tin oxide (ITO) and indium zinc oxide (IZO).
